(19) United States
(12) Patent Application Publication
(10) Pub. No.: US 2017/0345766 A1
(43) Pub. Date: Nov. 30, 2017

(54) DEVICES AND METHODS OF FORMING LOW RESISTIVITY NOBLE METAL INTERCONNECT WITH IMPROVED ADHESION

(71) Applicant: GLOBALFOUNDRIES Inc., Grand Cayman (KY)

(72) Inventors: Xunyuan ZHANG, Albany, NY (US); Frank W. MONT, Troy, NY (US); Errol Todd RYAN, Clifton Park, NY (US)

(73) Assignee: GLOBALFOUNDRIES Inc., Grand Cayman (KY)

(21) Appl. No.: 15/168,930

(22) Filed: May 31, 2016

(51) Int. Cl. H01L 23/532; H01L 21/768; H01L 21/311; H01L 23/528; H01L 23/522; H01L 21/285

(52) U.S. Cl. CPC H01L 23/53252; H01L 23/5329; H01L 23/528; H01L 23/5226; H01L 21/76877; H01L 21/76864; H01L 21/7685; H01L 21/31111; H01L 21/7684; H01L 21/76834; H01L 21/7682; H01L 21/28556; H01L 21/2855

(57) ABSTRACT

Devices and methods of fabricating integrated circuit devices for forming low resistivity interconnects with improved adhesion are provided. One method includes, for instance: obtaining an intermediate semiconductor interconnect device having a substrate, a cap layer, and a dielectric matrix including a set of trenches and a set of vias; depositing a metal interconnect material directly over and contacting a top surface of the dielectric matrix, wherein the metal interconnect material fills the set of trenches and the set of vias; depositing a barrier layer over a top surface of the device; annealing the barrier layer to diffuse the barrier layer to a bottom surface of the metal interconnect material; planarizing a top surface of the intermediate semiconductor interconnect device; and depositing a dielectric cap over the intermediate semiconductor interconnect device.

### FIELD OF THE INVENTION

The present invention relates to semiconductor devices and methods of fabricating semiconductor devices, and more particularly, to devices and methods of forming low resistivity metal interconnects having noble metals with an improved adhesion.

### BACKGROUND OF THE INVENTION

For 5 nm and beyond nodes, with the continually increasing demand for smaller circuit structures and faster device performance, copper line resistivity begins to climb, decreasing the performance of the nodes. The development of 5 nm nodes and smaller will likely require lowering the resistivity of the lines in the nodes. However, at these sizes, previous methods of lining trenches and vias can cause delamination of the barrier layer and the interconnect material from the device.

Therefore, it may be desirable to develop methods of fabricating nodes with lines that have a lower resistivity than copper at such a small size and that have an improved adhesion.

### BRIEF SUMMARY

The shortcomings of the prior art are overcome and additional advantage are provided through the provisions, in one aspect, a method that includes, for instance: obtaining an intermediate semiconductor interconnect device having a substrate, a cap layer, and a dielectric matrix including a set of trenches and a set of vias; depositing a metal interconnect material directly over and contacting a top surface of the dielectric matrix, wherein the metal interconnect material fills the set of trenches and the set of vias; depositing a barrier layer over a top surface of the semiconductor interconnect device; annealing the barrier layer to diffuse the barrier layer to a bottom surface of the metal interconnect material; planarizing a top surface of the intermediate semiconductor interconnect device removing the metal interconnect material above the set of trenches and the set of vias; and depositing a dielectric cap over the intermediate semiconductor interconnect device.

In another aspect, an intermediate device is provided which includes, for instance: an intermediate semiconductor interconnect device having a substrate, a cap layer, and a dielectric matrix including a set of trenches and a set of vias; a barrier layer over a top surface of the dielectric matrix material lining the set of trenches and the set of vias; a metal interconnect material directly over and contacting the barrier layer, wherein the metal interconnect material fills the set of trenches and the set of vias, and wherein the barrier layer is annealed; and a dielectric cap over the intermediate semiconductor interconnect device.

In another aspect, an device is provided which includes, for instance: an intermediate semiconductor interconnect device having a substrate, a cap layer, and a dielectric matrix including a set of trenches and a set of vias; a barrier layer over a top surface of the dielectric matrix material lining the set of trenches and the set of vias; a metal interconnect material directly over and contacting the barrier layer, wherein the metal interconnect material fills the set of trenches and the set of vias, and wherein the barrier layer is annealed; and a dielectric cap over the intermediate semiconductor interconnect device.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 depicts one embodiment of a method for forming an intermediate semiconductor interconnect structure, in accordance with one or more aspects of the present invention;

FIG. 2 depicts a cross-sectional elevation view of one embodiment of an intermediate semiconductor interconnect structure having a substrate, a cap layer, and a dielectric matrix including a set of trenches and a set of vias, in accordance with one or more aspects of the present invention;

FIG. 3 depicts the structure of FIG. 2 after depositing a metal interconnect material, in accordance with one or more aspects of the present invention;

FIG. 4 depicts the structure of FIG. 3 after depositing a barrier layer, in accordance with one or more aspects of the present invention;

FIG. 5 depicts the structure of FIG. 4 after annealing the barrier layer, in accordance with one or more aspects of the present invention;

FIG. 6 depicts the structure of FIG. 5 after planarizing a top surface of the intermediate semiconductor interconnect structure, in accordance with one or more aspects of the present invention;

FIG. 7 depicts the structure of FIG. 6 after depositing a sacrificial dielectric cap, in accordance with one or more aspects of the present invention;

FIG. 8 depicts the structure of FIG. 7 after depositing a block mask and forming an opening, in accordance with one or more aspects of the present invention;

FIG. 9 depicts the structure of FIG. 8 after forming a set of air-gaps and removing the sacrificial dielectric cap, in accordance with one or more aspects of the present invention; and

FIG. 10 depicts the structure of FIG. 9 after depositing a dielectric cap, in accordance with one or more aspects of the present invention;

FIG. 11 depicts a cross-sectional elevation view of one embodiment of an intermediate device having a substrate, a cap layer, a dielectric matrix, a set of trenches, a set of vias, a barrier layer lining the set of trenches and the set of vias, and a dielectric cap, in accordance with one or more aspects of the present invention;

### DETAILED DESCRIPTION

Aspects of the present invention and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the invention in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Note also that reference is made below to the drawings, which are not drawn to scale for ease of understanding, wherein the same reference numbers used throughout different figures designate the same or similar components.

Generally stated, disclosed herein are certain integrated circuits, which provide advantages over the above noted, existing semiconductor devices and fabrication processes. Advantageously, the integrated circuit device fabrication processes disclosed herein provide for semiconductor devices with a lower line resistivity than previously possible using traditional copper lines.

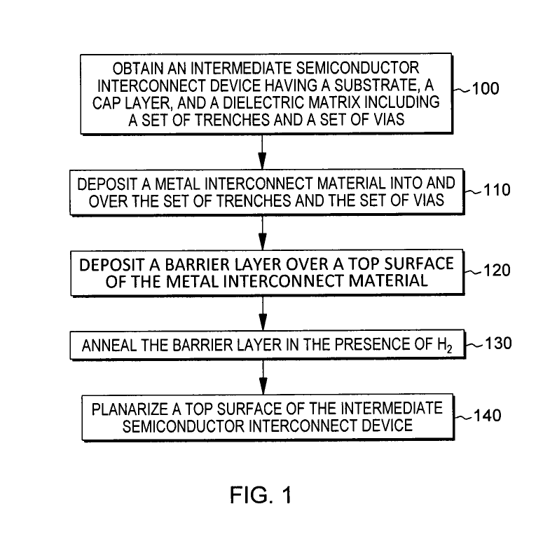

In one aspect, in one embodiment, as shown in FIG. 1, an integrated circuit device formation process in accordance with one or more aspects of the present invention may include, for instance: obtaining an intermediate semiconductor interconnect device having a substrate, a cap layer, and a dielectric matrix including a set of trenches and a set of vias 100; depositing a metal interconnect material into and over the set of trenches and the set of vias 110; depositing a barrier layer over a top surface of the metal interconnect material 120; annealing the barrier layer in the presence of H₂ 130; and planarizing a top surface of the intermediate semiconductor interconnect device 140.

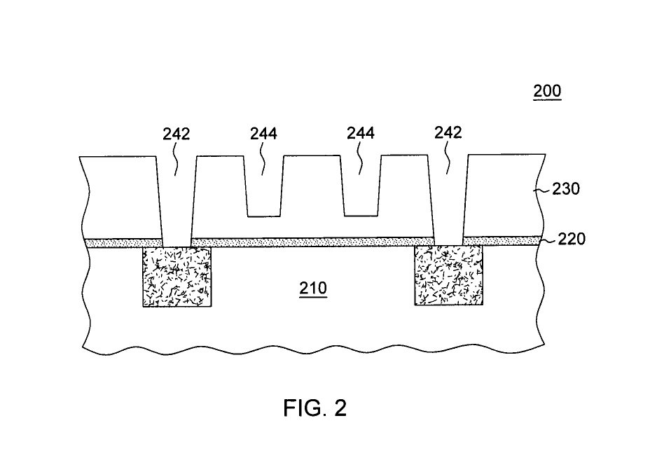

FIGS. 2-10 depict, by way of example only, one detailed embodiment of a portion of a semiconductor device formation process and a portion of an intermediate semiconductor interconnect structure, in accordance with one or more aspects of the present invention. Note that these figures are not drawn to scale in order to facilitate understanding of the invention, and that the same reference numerals used throughout different figures designate the same or similar elements.

FIG. 2 shows a portion of an intermediate semiconductor device generally denoted 200, depicted at an intermediate semiconductor fabrication stage. The device 200 may have been processed through initial device processing steps in accordance with the design of the device 200 being fabricated. For example, the device 200 may include, for instance, a substrate 210 with a cap layer 220, which may include a dielectric material, disposed on the substrate 210. The substrate 210 may be any suitable material, for example, silicon. Additionally, dielectric matrix 230 may be deposited on substrate 210 or cap layer 220. Dielectric matrix may include one or more dielectric materials, and may include a mixed matrix of materials or a plurality of layers of materials (not shown). Dielectric matrix 230 may include a set of vias 242 and a set of trenches 244. As illustrated in FIG. 2, the set of vias 242 may extend through the cap layer 220 to features below, whilst the set of trenches 244 may only extend into the dielectric matrix 230.

In another embodiment (not shown), the substrate of device 200 may be, for example, a silicon on insulator (SOI) substrate (not shown). For example, the SOI substrate may include an isolation layer (not shown), which may be a local buried oxide region (BOX) or any suitable material for electrically isolating transistors, aligned with the gate structure. In some embodiments, the device is a portion of a back end of line (BEOL) portion of an integrated circuit (IC).

As depicted in FIG. 2, using lithography and etching processes, the dielectric matrix 230 and/or the cap layer 220 may have been etched in the dielectric matrix 230 to define the set of vias 242 and the set of trenches 244. The etching may be performed by any suitable etching process, for example, a directional reactive ion etching (RIE).

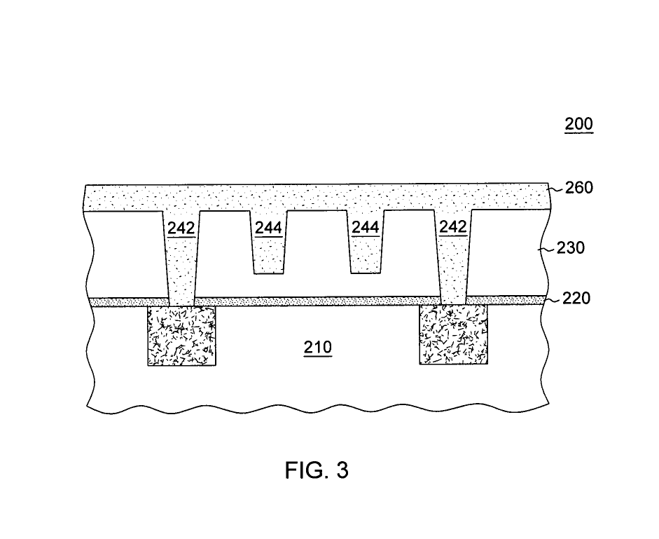

As depicted in FIG. 3, a metal interconnect material 260 is deposited directly over the dielectric matrix 230 by atomic layer deposition (ALD) or chemical vapor deposition (CVD) in some embodiments. The metal interconnect material is deposited, in some embodiments, between approximately 10 nm and approximately 20 nm in thickness, such that it fills the set of vias 242 (FIG. 2) and the set of trenches 244 (FIG. 2). The metal interconnect material 260 can include any noble metal, including but not limited to: ruthenium (Ru), niobium (Nb), rhodium (Rh), iridium (Ir), and platinum (PT). While copper (Cu) has traditionally been the interconnect material of choice, as the line width continues to get smaller for device, the resistivity of copper starts to grow. In contrast, noble metals can have a more desirable resistivity at smaller sizes.

For instance, Ru thin films have a nearly constant resistivity from 20 nm to 6 nm, unlike copper, which climbs consistently between 20 nm and 6 nm. At approximately 5 nm, Ru can have nearly the same resistivity as Cu, and can have a lower resistivity below 5 nm. Additionally, Ru shows no failure due to electromigration (EM), unlike many other interconnect materials. The time dependent dielectric breakdown (TDDB) of noble metal thin films can be at least 10 times better than copper. However, as will be further described below, the resistivity of the metal interconnect material 260 can be lowered even further by increasing the resistance of the layer adjacent to the metal interconnect material 260, such as barrier layer 250. Thus, altering the barrier layer 250 in terms of the composition to increase the resistance can lower the resistance of the metal interconnect material 260.

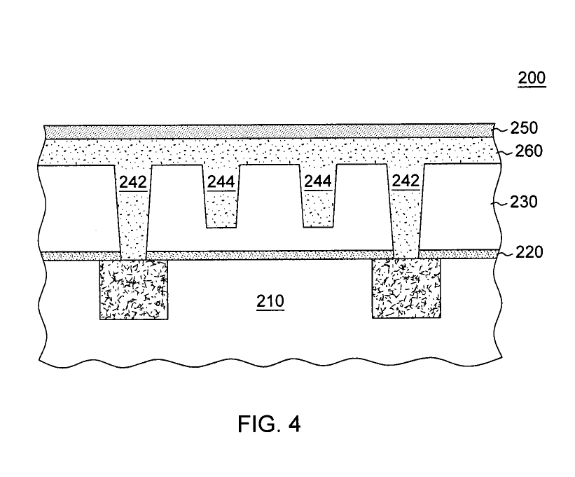

As depicted in FIG. 4, a barrier layer 250 may be deposited along a top surface of the metal interconnect material 260 by ALD, CVD, physical vapor deposition (PVD), or any other suitable deposition technique now known or later developed. For instance, the barrier layer 250 may have a component of manganese (Mn) and may be between approximately 1 nanometers (nm) thick and approximately 3 nm thick. Any deposition capable of forming a consistent thin film or thin layer of less than approximately 3 nm, as illustrated in FIG. 4, can be used to deposit the barrier layer 250.

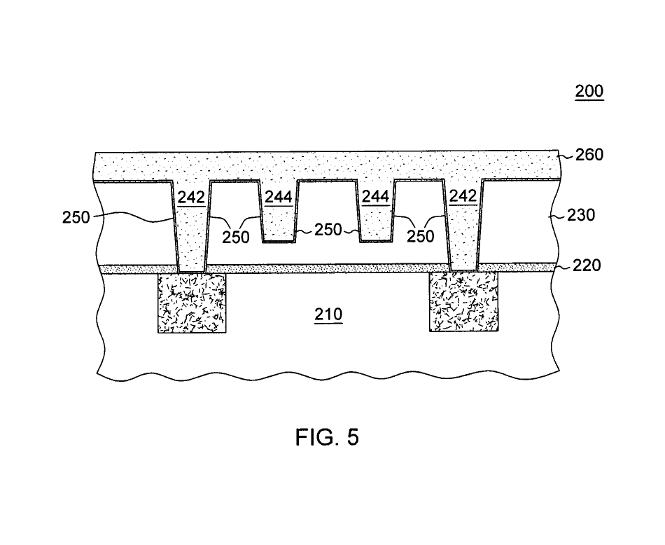

As depicted in FIG. 5, the barrier layer 250 can be annealed in the presence of H₂, which may be in ambient air. The annealing process can diffuse the Mn containing barrier layer through the metal interconnect material 260, driven by the presence of oxygen in the air, forming a barrier layer to form between the metal interconnect material 260 and the dielectric matrix 230. This method of applying the barrier layer 250 can increase adhesion of the barrier layer 260 and metal interconnect material 260 to dielectric matrix 230. For instance, depositing the barrier layer first by CVD, PVD, or AVD can result in delamination of the layers, possibly resulting in early device failure. Depositing the barrier layer 250 over the metal interconnect material 260 and diffusing it through increases the adhesion of all layers and, thus, results in a more stable device.

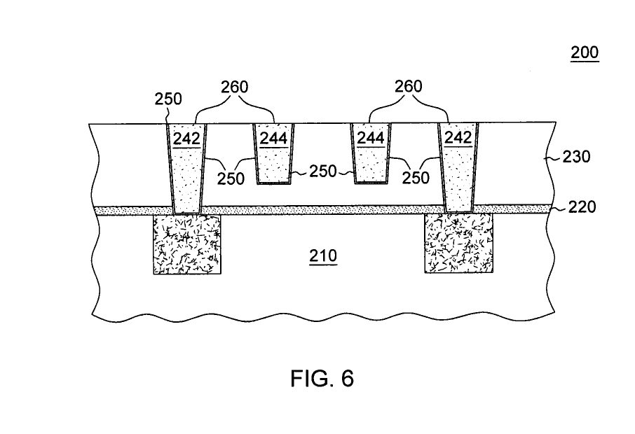

As depicted in FIG. 6, using, for example, chemical mechanical polishing, a top surface of device 200 can be planarized and polished, removing excess metal interconnect material 260 and providing a smooth surface on which to continue device fabrication. The presence of the relatively high resistivity Mn containing barrier layer on an outer surface of the low resistivity noble metal interconnect material decreases the effective resistivity of the metal interconnect. In this embodiment, the resistance of the metal interconnect material 260 can be significantly lowered whilst adhering well in the set of trenches 244 and the set of vias 242.

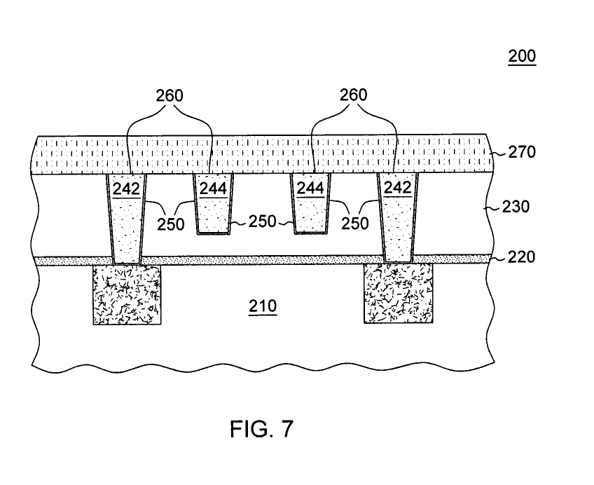

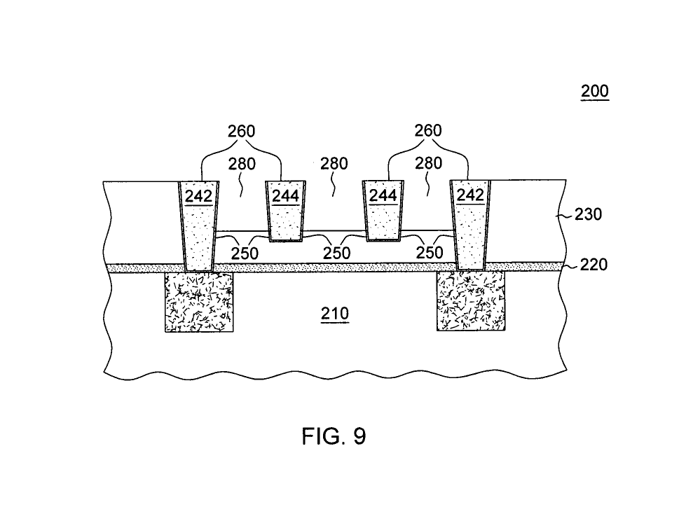

FIGS. 7-10 illustrate a further embodiment of incorporating a set of air-gaps 280 (FIG. 9) into device 200 by removing a portion of the dielectric matrix 230 between at least some of the set of trenches 244 and the set of vias 242. In some embodiments, air-gaps 280 can decrease the conductivity of metal interconnect material 260 even further.

As depicted in FIG. 7, in a further embodiment, the set of air-gaps 280 (FIG. 9) may be further incorporated into device 200, for instance, by depositing a sacrificial dielectric cap 270 over device 200. This cap is considered sacrificial as it is used for masking of the underlying structure, and not for functioning of the end device.

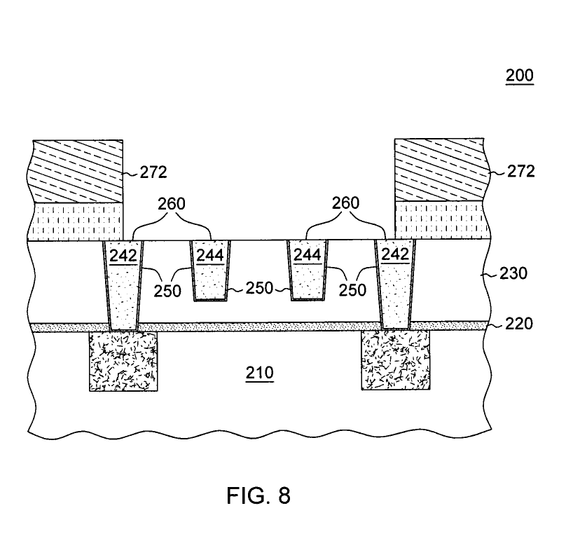

As depicted in FIG. 8, a block mask 272 can be formed by standard lithography and etching techniques, on a top surface of sacrificial dielectric cap 270, and the sacrificial dielectric cap 270 can be removed, for example by etching, to expose and form one or more openings over the set of trenches 244 and the set of vias 242 using any lithography techniques. After use, the block mask 272 can be removed by etching.

As depicted in FIG. 9, a portion of the barrier layer 250 between at least some of the set of vias 242 and the set of trenches 244 may be exposed, for instance, by forming a set of air-gaps 280 within the dielectric matrix 230. In some embodiments, regions of the dielectric matrix 230 may be damaged, for instance, between some or all of the set of trenches 244 and the set of vias 242, for example, to form the set of air-gaps 280. In some embodiments, H₂N₂ plasma is used to damage the dielectric matrix 230. The damaged material can be removed, for instance, with diluted hydrofluoric acid (HF), leaving air-gaps 280 between at least some of the set of vias 242 and the set of trenches 244. At the same time, sacrificial dielectric cap 270 may be removed with the same material.

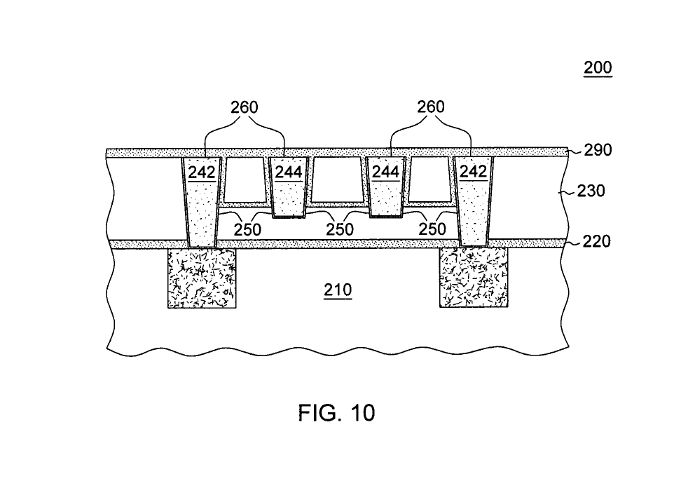

As depicted in FIG. 10, the dielectric cap 290 can coat the top surface of the device 200 and coating the inside surface of air-gaps 280 (FIG. 7). The presence of Mn containing barrier layer 250 at the surface of the metal interconnect material 260 will lower the effective resistance of metal interconnect material 260 in the end IC.

As depicted in FIG. 4, an intermediate device 200 of the claims may include, for example, a substrate 210, a cap layer 220, a dielectric matrix 230, a set of vias 242 extending through the cap layer 220, a set of trenches 244 extending into the dielectric matrix 230, a metal interconnect material 260 deposited directly over and contacting the trenches 244 and vias 242, and a barrier layer 250 deposited over the intermediate device 200. In these embodiments, the metal interconnect material may include a noble metal. The other materials are as described above.

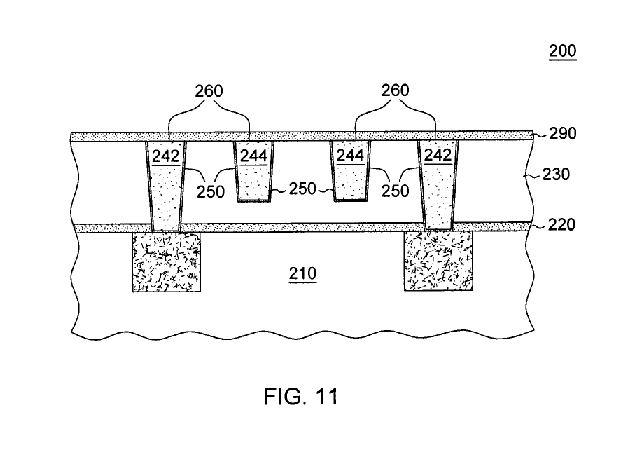

FIG. 11 depicts a device 900, which according to some embodiments, includes a substrate 210, a cap layer 220, a dielectric matrix 230, a set of vias 242 extending through the cap layer 220, a set of trenches 244 extending into the dielectric matrix 230, a barrier layer 250 lining the outside of trenches 244 and vias 242, a metal interconnect material 260 filling the trenches 244 and vias 242, and a dielectric cap 290. In these embodiments, the metal interconnect material 260 may include a noble metal. The other materials are as described above.

It should be appreciated that the novel intermediate semiconductor interconnect devices and methods of forming the same disclosed above lower the resistance of BEOL interconnect formations and lines whilst improving the adhesion of the layers. According to embodiments, surface scatter of the device is reduced by altering the material of the interconnect itself, and increasing the resistance and adhesion of the barrier layer decreases the resulting resistance of the interconnect material. Noble metals as interconnect materials are advantageous as the electromigration phenomenon is reduced, in part due to the higher melting point of the metals. Additionally, noble metals are more resistant to oxidation, allowing for easier oxidation of the barrier layers.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method comprising:
obtaining an intermediate semiconductor interconnect device having a substrate, a cap layer, and a dielectric matrix including a set of trenches and a set of vias;
depositing a metal interconnect material directly over and contacting a top surface of the dielectric matrix, wherein the metal interconnect material fills the set of trenches and the set of vias;
depositing a barrier layer over a top surface of the semiconductor interconnect device;
annealing the barrier layer to diffuse the barrier layer to a bottom surface of the metal interconnect material and interfacing the dielectric matrix;
planarizing a top surface of the intermediate semiconductor interconnect device removing the metal interconnect material above the set of trenches and the set of vias; and
depositing a dielectric cap over the intermediate semiconductor interconnect device.

2. The method of claim 1, wherein the barrier layer comprises a manganese containing material.

3. The method of claim 1, wherein the metal interconnect material comprises a noble metal.

4. The method of claim 3, wherein the noble metal comprises one of a group including: ruthenium (Ru), niobium (Nb), rhodium (Rh), iridium (Ir), and platinum (PT).

5. The method of claim 1, wherein the annealing is done in the presence of H₂, and oxygen drives the diffusion.

6. The method of claim 1, further comprising:
depositing, prior to the depositing the dielectric cap, a sacrificial dielectric cap and a block mask over the intermediate semiconductor interconnect device; and
forming a set of air-gaps between at least a portion of the set of trenches and the set of vias, removing the sacrificial dielectric cap with a wet chemical.

7. The method of claim 6, wherein the wet chemical comprises dilute hydrofluoric acid (HF).

8. The method of claim 6, wherein the depositing the dielectric cap forms a set of air-gaps in a region between the set of vias and the set of trenches.

9. The method of claim 1, wherein the barrier layer comprises a thickness of approximately 1 nm to approximately 3 nm and wherein the metal interconnect material is deposited between approximately 10 nm and approximately 20 nm in thickness.

10. The method of claim 9, wherein the barrier layer is deposited by one of a group comprising: atomic layer deposition (ALD), chemical vapor deposition (CVD), and physical vapor deposition (PVD), and wherein the metal interconnect material is deposited by one of a group comprising: CVD and ALD.

11. An intermediate device comprising:
an intermediate semiconductor interconnect device having a substrate, a cap layer, and a dielectric matrix including a set of trenches and a set of vias;
a metal interconnect material directly over and contacting a top surface of the dielectric matrix, wherein the metal interconnect material fills the set of trenches and the set of vias; and
a barrier layer over a top surface of the semiconductor interconnect device.

12. The device of claim 11, further comprising:
a set of air-gaps between at least some of the set of vias and the set of trenches.

13. The device of claim 11, wherein the barrier layer comprises a Mn containing material.

14. The device of claim 11, wherein the metal interconnect material comprises a noble metal.

15. The device of claim 14, wherein the noble metal comprises one of a group including: ruthenium (Ru), niobium (Nb), rhodium (Rh), iridium (Ir), and platinum (PT).

16. A device comprising:
an intermediate semiconductor interconnect device having a substrate, a cap layer, and a dielectric matrix including a set of trenches and a set of vias;
a barrier layer over a top surface of the dielectric matrix material lining the set of trenches and the set of vias;
a metal interconnect material directly over and contacting the barrier layer, wherein the metal interconnect material fills the set of trenches and the set of vias, and wherein the barrier layer is annealed; and
a dielectric cap over the intermediate semiconductor interconnect device.

17. The device of claim 16, further comprising:
a set of air-gaps between at least some of the set of vias and the set of trenches.

18. The device of claim 16, wherein the barrier layer comprises a Mn containing material.

19. The device of claim 16, wherein the metal interconnect material comprises a noble metal.

20. The device of claim 19, wherein the noble metal comprises one of a group including: ruthenium (Ru), niobium (Nb), rhodium (Rh), iridium (Ir), and platinum (PT).
